(19) United States
(12) Patent Application Publication
(10) Pub. No.: US 2015/0307358 A1
(43) Pub. Date: Oct. 29, 2015

(54) GRAPHENE SYNTHESIZING APPARATUS

(71) Applicant: SAMSUNG TECHWIN CO., LTD., Changwon-city (KR)

(72) Inventor: Jonghyuk YOON, Changwon-city (KR)

(73) Assignee: SAMSUNG TECHWIN CO., LTD., Changwon-city (KR)

(21) Appl. No.: 14/443,905

(22) PCT Filed: Oct. 2, 2013
(86) PCT No.: PCT/KR2013/008815

§ 371 Date: May 19, 2015

(30) Foreign Application Priority Data
Nov. 19, 2012 (KR) 10-2012-0131108

(51) Int. Cl. C01B 31/04; C23C 16/54; C23C 16/26

(52) U.S. Cl. CPC C01B 31/0453; C23C 16/26; C23C 16/54

(57) ABSTRACT

Provided is a graphene synthesizing apparatus. The graphene synthesizing apparatus includes: a heater unit configured to apply heat onto a continuous catalyst metal film; a susceptor unit disposed between the catalyst metal film and the heater unit to uniformly provide the heat of the heater unit to the catalyst metal film; and a raw material supply unit configured to provide a raw material to a side of the catalyst metal film.

### TECHNICAL FIELD

The inventive concept relates to a synthesizing apparatus, and more particularly, to a graphene synthesizing apparatus.

### BACKGROUND ART

Recently, carbon-based materials such as carbon nanotube, diamond, graphite, and graphene are researched in various fields. Among them, carbon nanotube is spotlighted since the 1990s. However, recently, sheet-structure graphene is attracting much attention. Graphene is a film material with a thickness of several nm in which carbon atoms are two-dimensionally arranged. Since electric charges act as zero effective mass particles in graphene, the graphene has very high electrical conductivity and also has high thermal conductivity and elasticity.

Thus, extensive research has been conducted on the characteristics of graphene, and research is conducted to use the graphene in various fields. Due to its high electrical conductivity and elasticity, the graphene may be suitably applied to transparent flexible devices.

### DETAILED DESCRIPTION OF THE INVENTIVE CONCEPT

### Technical Problem

Chemical vapor deposition (CVD) is used to synthesize graphene. The CVD is a method that installs a catalyst metal film formed of catalyst metal such as copper or platinum in an internal space of a graphene synthesizing chamber, injects hydrocarbon such as methane or ethane in to the internal space of the graphene synthesizing chamber, and then heats the internal space of the graphene synthesizing chamber to synthesize graphene on the surface of the catalyst metal film.

As described above, the graphene has very useful characteristics. However, since a relatively large amount of time is taken to set a high-temperature environment for graphene synthesis, it is difficult to economically mass-produce a large-area graphene sheet.

Such a graphene synthesizing apparatus is disclosed in Korean Patent Application Publication No. 2012-0088524 (Title of Invention: Graphene Synthesizing Apparatus and Method, Applicant: Samsung Techwin Co., Ltd. and SUNGKYUNKWAN University Foundation for Corporate Collaboration).

### Technical Solution

Exemplary embodiments of the inventive concept provide graphene synthesizing apparatuses that may synthesize graphene rapidly and continuously.

According to an aspect of the inventive concept, there is provided a graphene synthesizing apparatus including: a heater unit configured to apply heat onto a continuous catalyst metal film; a susceptor unit disposed between the catalyst metal film and the heater unit to uniformly provide the heat of the heater unit to the catalyst metal film; and a raw material supply unit configured to provide a raw material to a side of the catalyst metal film.

### Advantageous Effects

According to the exemplary embodiments of the inventive concept, when graphene is continuously synthesized, since the heat applied from the heater unit may be uniformly provided, graphene may be rapidly and continuously synthesized. Also, according to the exemplary embodiments of the inventive concept, since uniform heat may be supplied to a synthesis area, a uniform graphene film may be synthesized.

### DESCRIPTION OF THE DRAWINGS

FIG. 1 is a conceptual diagram illustrating a graphene synthesizing apparatus according to an exemplary embodiment of the inventive concept.

FIG. 2 is a conceptual diagram illustrating a graphene synthesizing apparatus according to another exemplary embodiment of the inventive concept.

### BEST MODE

According to an aspect of the inventive concept, there is provided a graphene synthesizing apparatus including: a heater unit configured to apply heat onto a continuous catalyst metal film; a susceptor unit disposed between the catalyst metal film and the heater unit to uniformly provide the heat of the heater unit to the catalyst metal film; and a raw material supply unit configured to provide a raw material to a side of the catalyst metal film.

Also, the heater unit may include: a first heater unit disposed on a first surface of the catalyst metal film; and a second heater unit disposed on a second surface of the catalyst metal film to face the first heater unit.

Also, the susceptor unit may be provided in plurality, and the plurality of susceptor units may be disposed in a multistage structure and the catalyst metal film may pass between the plurality of susceptor units.

Also, the graphene synthesizing apparatus may further include a raw material suction unit installed on another side of the catalyst metal film to face the raw material supply unit to suck the raw material.

Also, the graphene synthesizing apparatus may further include a tension maintaining roller configured to maintain the tension of the catalyst metal film while transferring the catalyst metal film.

Also, the graphene synthesizing apparatus may further include a chamber that forms an external appearance and in which the heater unit, the susceptor unit, and a portion of the raw material supply unit are installed.

Also, the graphene synthesizing apparatus may further include a vacuum pump installed at the chamber to control the internal pressure of the chamber.

Also, the raw material supply unit may include: a raw material storage unit installed outside the chamber to store the raw material; a raw material supply pipe connected to the raw material storage unit and installed to penetrate the chamber to flow the raw material therethrough; and a raw material spray nozzle connected to the raw material supply pipe to spray the raw material onto the catalyst metal film.

### MODE OF THE INVENTIVE CONCEPT

The inventive concept will be apparent from the exemplary embodiments described below in detail with reference to the accompanying drawings. The inventive concept may, however, be embodied in many different forms and should not be construed as being limited to the exemplary embodiments set forth herein; rather, these exemplary embodiments are provided so that this disclosure will be thorough and complete, and will fully convey the inventive concept to those of ordinary skill in the art. Therefore, the scope of the inventive concept is defined not by the detailed description of the exemplary embodiments but by the appended claims. The terminology used herein is for the purpose of describing the exemplary embodiments only and is not intended to limit the inventive concept. As used herein, the singular forms “a,” “an” and “the” are intended to include the plural forms as well, unless the context clearly indicates otherwise. It will be understood that the terms “comprise/include/have” and “comprising/including/having” used herein specify the presence of stated elements, steps, operations, or devices, but do not preclude the presence or addition of one or more other elements, steps, operations, or devices. Although terms such as “first” and “second” may be used herein to describe various elements or components, these elements or components should not be limited by these terms. These terms are only used to distinguish one element or component from another element or component.

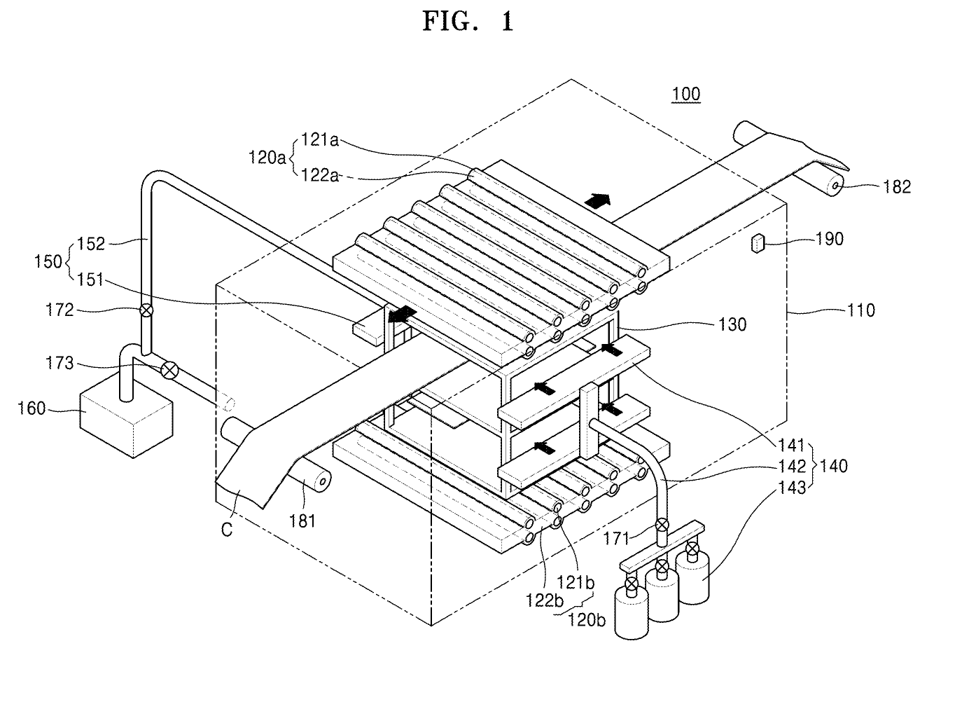

FIG. 1 is a conceptual diagram illustrating a graphene synthesizing apparatus 100 according to an exemplary embodiment of the inventive concept.

Referring to FIG. 1, the graphene synthesizing apparatus 100 may include a chamber 110 that forms an external appearance thereof. The chamber 110 may be formed such that all elements or some elements are installed in the chamber 110.

The graphene synthesizing apparatus 100 may include heater units 120a and 120b that are installed in the chamber 110. The heater units 120a and 120b may apply heat onto a continuous catalyst metal film C. In particular, the catalyst metal film C may be provided in the form of a continuous sheet.

Also, the heater unit 120a and 120b may include a halogen lamp or a far infrared ray heater in order to continuously synthesize graphene. The heater unit 120a and 120b may include: a heat supply source 121a and 121b configured to supply heat; and an external housing 122a and 122b formed to surround the heat supply source 121a and 121b.

The heat supply source 121a and 121b may be installed in the external housing 122a and 122b and may include any device and material that may generate heat. For example, the heat supply source 121a and 121b may be formed of a heater bar or a heater line.

Also, the external housing 122a and 122b may be formed of various materials. For example, the external housing 122a and 122b may be formed of a metal material or a carbon-containing material.

The heater unit 120a and 120b may include: a first heater unit 120a disposed on a first surface of the catalyst metal film C; and a second heater unit 120b installed to face the first heater unit 120a. The second heater unit 120b may be disposed on a second surface of the catalyst metal film C to apply heat to the catalyst metal film C.

The graphene synthesizing unit 100 may include a susceptor unit 130 that is disposed between the catalyst metal film C and the heater unit 120a and 120b to uniformly provide the heat of the heater unit 120a and 120b to the catalyst metal film C. The susceptor unit 130 may be formed in the shape of a plate. Also, the susceptor unit 130 may be formed of a graphite material or may be formed of a graphite material coated with silicon carbide (SiC). The material of the susceptor unit 130 is not limited thereto, and the susceptor unit 130 may include any material that may receive heat from the heater unit 120a and 120b and uniformly provide the heat to the catalyst metal film C.

The susceptor unit 130 may be provided in plurality. The plurality of susceptor units 130 may be formed in a multistage structure, and the susceptor units 130 may be formed to be spaced apart from each other by a predetermined distance. In particular, the catalyst metal film C may be disposed to pass between the plurality of susceptor units 130.

Also, the plurality of susceptor units 130 may be disposed variously with respect to the ground. For example, the plurality of susceptor units 130 may be disposed parallel to or perpendicular to the ground. However, for convenience of description, the following description will focus on the case where the susceptor units 130 are disposed parallel to the ground.

The graphene synthesizing apparatus 100 may include a raw material supply unit 140 that is installed on the side of the catalyst metal film C. The raw material supply unit 140 may be installed such that a portion thereof is disposed in the chamber 110.

The raw material supply unit 140 may include a raw material storage unit 143 that is installed outside the chamber 110 to store a raw material. The raw material storage unit 143 may be formed in the shape of a tank to store a raw material. Also, the raw material storage unit 143 may be provided in plurality to store different raw materials. In this case, the plurality of raw material storage units 143 may store the same raw material.

The raw material supply unit 140 may include a raw material supply pipe 142 that is connected to the raw material storage unit 143 to transfer the raw material. The raw material supply pipe 142 may be installed to penetrate the chamber 110.

Also, the raw material supply unit 140 may include a raw material spray nozzle 141 that is connected to the raw material supply pipe 142 to spray the raw material onto the catalyst metal film C. The raw material spray nozzle 141 may be disposed on the side of the catalyst metal film C. In particular, the raw material spray nozzle 141 may be disposed to spray the raw material between the plurality of susceptor units 130.

The raw material spray nozzle 141 may be provided in plurality. The plurality of raw material spray nozzles 141 may be disposed to be spaced apart from each other by a predetermined distance. In detail, the plurality of raw material spray nozzles 141 may be installed between the plurality of susceptor units 130 respectively. Thus, when the catalyst metal film C is transferred in the plurality of susceptor units 130, the raw material spray nozzle 141 may supply the raw material to the catalyst metal film C.

The raw material supply unit 140 may include a first block valve 171 that is installed at one or more of the raw material storage unit 143 and the raw material supply pipe 142 to control the supply of the raw material. In response to an external control signal, the first block valve 171 may open or close at least one of the raw material storage unit 143 and the raw material supply pipe 142 to control the supply of the raw material.

The graphene synthesizing apparatus 100 may include a vacuum pump 160 that is installed at the chamber 110 to control the internal pressure of the chamber 110. Since the vacuum pump 160 is similar to a general vacuum pump, detailed descriptions thereof will be omitted for conciseness.

The graphene synthesizing apparatus 100 may include a raw material suction unit 150 a portion of which is installed in the chamber 110. The raw material suction unit 150 may be installed to face the raw material supply unit 140.

In detail, the raw material suction unit 150 may include a raw material suction nozzle 151 that is configured to suck the raw material. The raw material suction nozzle 151 may be installed to face the raw material spray nozzle 141.

The raw material suction unit 150 may include a raw material discharge pipe 152 that is configured to transfer the raw material sucked from the raw material suction nozzle 151. The raw material discharge pipe 152 may be connected to the raw material suction nozzle 151.

The raw material suction unit 150 may include a discharge pump (not illustrated) that is configured to discharge the raw material flowing through the raw material discharge pipe 152. The discharge pump may be formed separately from the vacuum pump 160, or the vacuum pump 160 may function as the discharge pump. For convenience of description, the following description will focus on the case where the vacuum pump 160 and the discharge pump are identical to each other. When the vacuum pump 160 and the discharge pump are identical to each other, the raw material discharge pipe 152 may be connected to the vacuum pump 160.

The graphene synthesizing apparatus 100 may include a second block valve 172 that is installed at the vacuum pump 160 to control the amount of a fluid sucked by the vacuum pump 150. Also, the graphene synthesizing apparatus 100 may include a third block valve 173 that is installed at the raw material suction unit 150 to control the amount of the sucked raw material. The third block valve 173 may be installed at the raw material discharge pipe 152.

The second block valve 172 and the third valve 173 may be formed similar to each other. In detail, the second block valve 172 and the third valve 173 may be operate to maintain a predetermined pressure.

For example, the second block valve 172 may control the amount of a fluid flowing into the vacuum pump 160 so that the chamber 110 may maintain a predetermined internal pressure. Also, the third block valve 173 may control the amount of the raw material moving through the raw material discharge pipe 152 so that the raw material discharge pipe 152 may maintain a predetermined internal pressure.

The graphene synthesizing apparatus 100 may include tension maintaining rollers 181 and 182 that are configured to maintain the tension of the catalyst metal film C while transferring the catalyst metal film C. The tension maintaining roller 181 and 182 may be provided in plurality. In detail, the tension maintaining roller 181 and 182 may include a first tension maintaining roller 181 that is installed at a portion where the catalyst metal film C is inserted into the chamber 110. Also, the tension maintaining roller 181 and 182 may include a second tension maintaining roller 182 that is installed at a portion where the catalyst metal film C is extracted from the chamber 110.

The first tension maintaining roller 181 and the second tension maintaining roller 182 may prevent the catalyst metal film C from sinking due to the load of the catalyst metal film C. In particular, the first tension maintaining roller 181 and the second tension maintaining roller 182 may prevent a portion of the catalyst metal film C, which is disposed between the susceptor units 130, from sinking due to the load thereof.

In this case, the first tension maintaining roller 181 and the second tension maintaining roller 182 may be disposed at various positions. For example, the first tension maintaining roller 181 and the second tension maintaining roller 182 may be installed in the chamber 110 as illustrated in FIG. 1. In this case, a first roller cooling unit (not illustrated) and a second roller cooling unit (not illustrated) may be installed respectively at the first tension maintaining roller 181 and the second tension maintaining roller 182 to prevent the first tension maintaining roller 181 and the second tension maintaining roller 182 from being heated. In particular, the first roller cooling unit and the second roller cooling unit may be formed such that a coolant or a refrigerant may be circulated to cool the first tension maintaining roller 181 and the second tension maintaining roller 182 respectively. The first roller cooling unit and the second roller cooling unit are not limited thereto and may include any device that may cool the first tension maintaining roller 181 and the second tension maintaining roller 182 respectively.

Also, the first tension maintaining roller 181 and the second tension maintaining roller 182 may be installed outside the chamber 110. In particular, when the first tension maintaining roller 181 and the second tension maintaining roller 182 are disposed outside the chamber 110, the chamber 110 may be provided in plurality such that they are formed to be connected to each other. That is, other chambers may be installed to be connected to the chamber 110 in which the susceptor unit 130 is installed, and the first tension maintaining roller 181 and the second tension maintaining roller 182 may be installed in the chamber in which the susceptor unit 130 is not installed.

For convenience of description, the following description will focus on the case where the first tension maintaining roller 181 and the second tension maintaining roller 182 are installed outside the chamber 110 in which the susceptor unit 130 is installed.

The graphene synthesizing apparatus 100 may include a temperature measuring unit 190 that is installed at the chamber 110 to measure the internal temperature of the chamber 110. The temperature measuring unit 190 may measure the internal temperature of the chamber 110 and provide the measured temperature to a control unit (not illustrated). Also, the control unit may control the operations of the heater units 120a and 120b and the vacuum pump 160 on the basis of the temperature measured by the temperature measuring unit 190.

Also, the graphene synthesizing apparatus 100 may include a chamber cooling unit (not illustrated) that may control the internal temperature of the chamber 110. The chamber cooling unit may control the temperature of the chamber 110 by circulating a coolant or a refrigerant along the outside of the chamber 110. In particular, the chamber cooling unit may control the temperature of the chamber 110 according to a control signal received from the control unit on the basis of the temperature measured by the temperature measuring unit 190.

In detail, when the temperature measured by the temperature measuring unit 190 is equal to or higher than a predetermined temperature, the control unit may operate the chamber cooling unit to cool the chamber 110. Also, when the temperature measured by the temperature measuring unit 190 is lower than the predetermined temperature, the control unit may stop the operation of the chamber cooling unit to prevent the chamber 110 from being cooled.

Hereinafter, the operations of the graphene synthesizing apparatus 100 will be described in detail.

When the graphene synthesizing apparatus 100 operates, the first tension maintaining roller 181 and the second tension maintaining roller 182 may operate to move the catalyst metal film C in the chamber 110. In this case, the metal forming the catalyst metal film C may include at least one selected from the group consisting of nickel (Ni), cobalt (Co), iron (Fe), platinum (Pt), gold (Au), aluminum (Al), chromium (Cr), copper (Cu), magnesium (Mg), manganese (Mn), molybdenum (Mo), rhodium (Rh), silicon (Si), tantalum (Ta), titanium (Ti), and tungsten (W). However, for convenience of description, the following description will focus on the case where the catalyst metal film C is formed of copper.

As described above, when the catalyst metal film C is supplied, the catalyst metal film C may move between the susceptor units 130. In this case, the raw material supply unit 140 may supply the raw material to the surface of the catalyst metal film C.

In detail, the raw material may include at least one selected from the group consisting of carbon-containing materials such as carbon monoxide, methane, ethane, ethylene, ethanol, acetylene, propane, propylene, butane, butadiene, pentane, pentene, cyclopentadiene, hexane, cyclohexane, benzene, and toluene. However, for convenience of description, the following description will focus on the case where the raw material includes methane.

For example, as the internal temperature of the chamber increases, methane gas (CH4) (i.e., a gaseous carbon supply source) is divided into carbon atoms and hydrogen atoms and then the carbon atoms are absorbed into the surface of the catalyst metal. The carbon atoms are diffused in the surface of the catalyst metal.

The raw material may include hydrogen in addition to the carbon supply material. In this case, hydrogen may function to remove impurities of the surface of the catalyst metal film C and transmit the heat of the heater units 120a and 120b.

During the supply of the raw material, the heater units 120a and 120b may be operated to supply heat to the surface of the catalyst metal film C. In this case, the heat generated by the heater units 120a and 120b may be transmitted to the susceptor unit 130 to heat the susceptor unit 130, so that the susceptor unit 130 may apply heat to the surface of the catalyst metal film C. In particular, the temperature of the susceptor unit 130 may be increased by the heat transmitted through the heater units 120a and 120b, and the internal temperature of the chamber 110 may be maintained at a high temperature of about 900° C. to about 1080° C.

When the heat is applied from the susceptor unit 130, graphene may be synthesized at the surface of the catalyst metal film C. In this case, the graphene may be synthesized by chemical vapor deposition (CVD). Examples of the CVD may include thermal chemical vapor deposition (T-CVD), rapid thermal chemical vapor deposition (RT-CVD), inductive coupled plasma chemical vapor deposition (ICP-CVD), and plasma enhanced chemical vapor deposition (PE-CVD).

While the raw material is supplied to the catalyst metal film C, the raw material suction unit 150 may suck the raw material on the opposite side of the raw material supply unit 140. In particular, the raw material may be sucked by the raw material suction nozzle 151, and the raw material may be discharged through the raw material discharge pipe 152. Also, during the above operation, the vacuum pump 160 may be operated to maintain the internal pressure of the chamber 110.

When the raw material is supplied through the raw material supply unit 140 and the raw material suction unit 150 is operated, the concentration of the raw material between the susceptor units 130 may be maintained to be uniform. Also, in the above case, the flow of the raw material may be smoothed, so that the concentration of the raw material between the susceptor units 130 may be maintained to be uniform.

Thus, since the uniform concentration of the raw material may be maintained at the surface of the catalyst metal film C, graphene synthesis may be smoothly performed.

The graphene formed at the surface of the catalyst metal film C may be removed by stacking a carrier member (not illustrated) on the graphene and etching the catalyst metal film C. The carrier member may include, for example, polydimethylsiloxane (PDMS).

After the removal of the catalyst metal film C, the graphene may be carried by the carrier member and may be transferred to a target substrate (not illustrated). The target substrate may include, for example, polyethyleneterephthalate (PET).

Thus, when graphene is continuously synthesized by the graphene synthesizing apparatus 100, since the heat applied from the heater units 120a and 120b may be uniformly provided, the graphene may be synthesized rapidly and continuously. Also, since uniform heat may be supplied to a synthesis area, a uniform graphene film may be synthesized by the graphene synthesizing apparatus 100.

In particular, in the case of using the conventional CVD method to form graphene, since graphene is synthesized at a high temperature of about 900° C. to about 1080° C., heating or cooling may not be freely performed. In particular, in the case of using the conventional method, a large amount of time may be taken to perform heating or cooling.

However, the graphene synthesizing apparatus 100 according to the exemplary embodiment of the inventive concept may effectively and uniformly supply the heat of the heater units 120a and 120b through the susceptor unit 130.

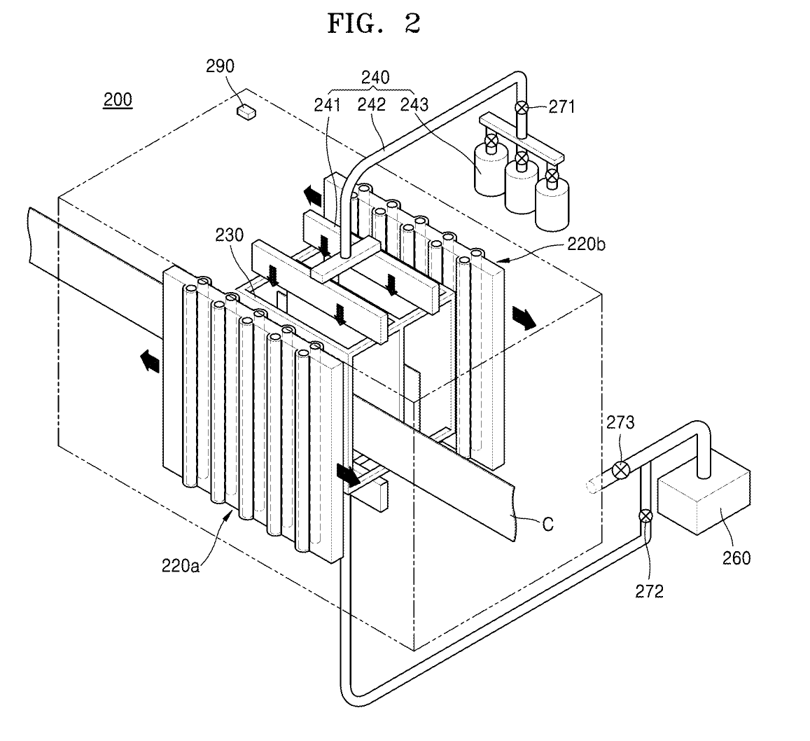

FIG. 2 is a conceptual diagram illustrating a graphene synthesizing apparatus 200 according to another exemplary embodiment of the inventive concept.

Referring to FIG. 2, the graphene synthesizing apparatus 200 may include a chamber 210, heater units 220a and 220b, a susceptor unit 230, a raw material supply unit 240, a raw material suction unit 250, a vacuum pump 260, a first block valve 271, a second block valve 272, a third block valve 273, a temperature measuring unit 290, and a chamber cooling unit (not illustrated). In this case, the chamber 210, the heater units 220a and 220b, the susceptor unit 230, the raw material supply unit 240, the raw material suction unit 250, the vacuum pump 260, the first block valve 271, the second block valve 272, the third block valve 273, the temperature measuring unit 290, and the chamber cooling unit may be formed similarly to the chamber 110, the heater units 120a and 120b, the susceptor unit 130, the raw material supply unit 140, the raw material suction unit 150, the vacuum pump 160, the first block valve 171, the second block valve 172, the third block valve 173, the temperature measuring unit 190, and the chamber cooling unit that have been described above with reference to FIG. 1.

In detail, the heater unit 220a and 220b may include a first heater unit 220a and a second heater unit 220b, and the raw material supply unit 240 may include a raw material spray nozzle 241, a raw material supply pipe 242, and a raw material storage unit 243. Also, the raw material suction unit 250 may include a raw material suction nozzle 251 and a raw material discharge pipe 252.

The first heater unit 220a, the second heater unit 220b, and the susceptor unit 230 may be disposed perpendicular to the ground. In this case, a plurality of susceptor units 230 may be disposed to be spaced apart from each other by a predetermined distance, so that the catalyst metal film C may move between the susceptor units 230. In particular, the catalyst metal film C may move between the susceptor units 230 in a direction perpendicular to the ground.

For the operation of the graphene synthesizing apparatus 200, graphene may be synthesized in a similar way as described above.

For example, when the catalyst metal film C is transferred in a state perpendicular to the ground, the raw material supply unit 240 may supply the raw material to the side of the catalyst metal film C. In this case, the raw material spray nozzle 241 may spray the raw material from the top of FIG. 2 to the side of the catalyst metal film C.

When the raw material is sprayed as above, the raw material suction unit 250 may suck the raw material. In particular, the raw material may be sucked by the raw material suction nozzle 251 and may be discharged to the outside through the raw material discharge pipe 252. In this case, the heat supplied from the heater units 220a and 220b may be applied to the surface of the catalyst metal film C through the susceptor unit 230.

When the heat is applied to the surface of the catalyst metal film C as above, the catalyst metal film C may be deformed. In particular, the catalyst metal film C may be lengthened by the heat. In this case, since the catalyst metal film C is transferred in a state perpendicular to the ground, it may not be transferred to the susceptor unit 230 due to the load thereof.

When the catalyst metal film C is transferred as above, the raw material may be supplied to synthesize graphene. Since a graphene synthesizing method has been described above in detail, detailed descriptions thereof will be omitted herein for conciseness.

Also, during the above operation, the vacuum pump 260 may be operated to maintain the internal pressure of the chamber 210. In this case, the second block valve 272 and the third block valve 273 may be opened or blocked according to a predetermined pressure value to control the discharge of the raw material and the internal pressure of the chamber 210.

The graphene manufactured as above may be discharged to the outside. In this case, a method of removing the catalyst metal film C and a method of using the discharged graphene are similar to those described above, detailed descriptions thereof will be omitted herein for conciseness.

Thus, when graphene is continuously synthesized by the graphene synthesizing apparatus 200, since the heat applied from the heater units 220a and 220b may be uniformly provided, the graphene may be synthesized rapidly and continuously. Also, since uniform heat may be supplied to a synthesis area, a uniform graphene film may be synthesized by the graphene synthesizing apparatus 200.

While the inventive concept has been particularly shown and described with reference to exemplary embodiments thereof, it will be understood that various changes in form and details may be made therein without departing from the spirit and scope of the following claims.

### INDUSTRIAL APPLICABILITY

According to the exemplary embodiments of the inventive concept, a graphene manufacturing method may be provided to manufacture graphene with improved electrical characteristics, so that large-area graphene may be commercialized. For example, the exemplary embodiments of the inventive concept may be applied to transparent electrodes including graphene, active layers, display devices including the same, electronic devices, photoelectric devices, batteries, and solar batteries.

1. A graphene synthesizing apparatus comprising:
a heater unit configured to apply heat onto a continuous catalyst metal film;
a susceptor unit disposed between the catalyst metal film and the heater unit to uniformly provide the heat of the heater unit to the catalyst metal film; and
a raw material supply unit configured to provide a raw material to a side of the catalyst metal film.

2. The graphene synthesizing apparatus of claim 1, wherein the heater unit comprises:
a first heater unit disposed on a first surface of the catalyst metal film; and
a second heater unit disposed on a second surface of the catalyst metal film to face the first heater unit.

3. The graphene synthesizing apparatus of claim 1, wherein
the susceptor unit is provided in plurality, and
the plurality of susceptor units are disposed in a multistage structure and the catalyst metal film passes between the plurality of susceptor units.

4. The graphene synthesizing apparatus of claim 1, further comprising a raw material suction unit installed on another side of the catalyst metal film to face the raw material supply unit to suck the raw material.

5. The graphene synthesizing apparatus of claim 1, further comprising a tension maintaining roller configured to maintain the tension of the catalyst metal film while transferring the catalyst metal film.

6. The graphene synthesizing apparatus of claim 1, further comprising a chamber that forms an external appearance and in which the heater unit, the susceptor unit, and a portion of the raw material supply unit are installed.

7. The graphene synthesizing apparatus of claim 6, further comprising a vacuum pump installed at the chamber to control the internal pressure of the chamber.

8. The graphene synthesizing apparatus of claim 6, wherein the raw material supply unit comprises:
a raw material storage unit installed outside the chamber to store the raw material;
a raw material supply pipe connected to the raw material storage unit and installed to penetrate the chamber to flow the raw material therethrough; and
a raw material spray nozzle connected to the raw material supply pipe to spray the raw material onto the catalyst metal film.

9. A graphene synthesizing method comprising:
emitting heat from a heater unit to heat a susceptor unit;
providing the heat of the heater unit uniformly through the susceptor unit to a catalyst metal film that is continuously provided; and
providing a raw material to a side of the catalyst metal film to synthesize graphene.

10. The graphene synthesizing method of claim 9, wherein the heater unit emits heat on both sides of the catalyst metal film.

11. The graphene synthesizing method of claim 9, wherein
the susceptor unit is provided in plurality and the plurality of susceptor units are disposed in a multistage structure, and
the catalyst metal film continuously passes between the plurality of susceptor units.

12. The graphene synthesizing method of claim 9, further comprising sucking the raw material on a side opposite to a side on which the raw material is supplied.

13. The graphene synthesizing method of claim 9, wherein the catalyst metal film is transferred with the tension thereof maintained.

14. The graphene synthesizing method of claim 9, wherein the graphene is synthesized in a vacuum environment.
